(19) United States
(12) Patent Application Publication
(10) Pub. No.: US 2011/0217467 A1
(43) Pub. Date: Sep. 8, 2011

(54) VACUUM PROCESSING APPARATUS AND VACUUM PROCESSING METHOD

(75) Inventors: Hajime SAHASE, Fuchu-shi (JP); Naoki Watanabe, Kawasaki-shi (JP); Ge Xu, Hachioji-shi (JP)

(73) Assignee: CANON ANELVA CORPORATION, Kawasaki-shi (JP)

(21) Appl. No.: 13/037,689

(22) Filed: Mar. 1, 2011

(30) Foreign Application Priority Data
Mar. 3, 2010 (JP) 2010-046043
Dec. 15, 2010 (JP) 2010-278803

(51) Int. Cl. C23C 14/56; B05C 11/00

(52) U.S. Cl. 427/255.7; 118/695

(57) ABSTRACT

A vacuum processing apparatus includes two process chambers and three load-lock chambers which are alternately connected in series, and a transferring device which transfers a plurality of carriers only between the process chamber and the load-lock chambers that are adjacent to each other. A substrate undergoes deposition processing when the carrier is positioned in the process chamber by the transferring device, and the substrate is replaced when the carrier is positioned in the load-lock chamber by the transferring device.

### BACKGROUND OF THE INVENTION

1. Field of the Invention

The present invention relates to a vacuum processing apparatus and vacuum processing method which are suitable for vacuum processing a large number of substrates.

2. Description of the Related Art

A deposition apparatus in which one load-lock chamber LL is connected to one process chamber PC has conventionally been employed to deposit about one to three layers on a target material such as a substrate (see, for example, Japanese Patent Laid-Open No. 9-27297).

In such a deposition apparatus including only one process chamber PC and one load-lock chamber LL, deposition cannot be performed in the process chamber PC while the substrate is replaced in the load-lock chamber LL, so there is a limit beyond which the substantial capacity utilization rate can no longer improve, and it is difficult to improve the productivity (throughput) of deposition processing.

Also, in a deposition apparatus including only one process chamber PC and one load-lock chamber LL, a device which transfers a vacuum vessel while holding a substrate on a carrier is often used. In such a device, the substrate is often attached/detached after the carrier is removed from the vacuum vessel, so a large number of processing steps are required to attach/detach substrates, thus hindering an improvement in productivity.

Under the circumstance, to shorten the operation time in the load-lock chamber LL, a method of disposing load-lock chambers LL on the upstream and downstream sides, respectively, of the process chamber PC, and passing the substrate in one direction is adopted (see, for example, Japanese Patent Laid-Open Nos. 7-243037 and 11-22915).

A technique disclosed in, for example, Japanese Patent Laid-Open No. 7-243037 uses a vacuum processing apparatus in which a plurality of process chambers PC are arranged between a load chamber and an unload chamber. This vacuum processing apparatus can transfer a substrate while holding it on a carrier, and therefore can continuously form multilayer films on the substrate (target material).

However, the technique described in Japanese Patent Laid-Open No. 7-243037 requires a complex mechanism for transferring, inside a vacuum vessel, the carrier (or a holder) which holds the substrate. This makes it difficult to reduce the cost of a deposition apparatus. Also, if only a few layers are stacked on the substrate, the operation times in the load chamber LC and unload chamber UL become relatively long, and a considerable number of carriers must be prepared to improve the operating ratio of the process chamber PC. This again makes it difficult to reduce the cost of a deposition apparatus.

### SUMMARY OF THE INVENTION

The present invention has been made in consideration of the above-mentioned problems, and realizes a vacuum processing apparatus and vacuum processing method that can improve the productivity of deposition processing and contribute to a reduction in cost.

In order to solve the aforementioned problems, the present invention provides a vacuum processing apparatus comprising: not less than one process unit; load-lock chambers which are more than the process unit by one; carriers which are more than the process unit by not less than one; and a transferring device which transfers the carriers between the process unit and the load-lock chambers that are adjacent to each other, wherein the process unit and the load-lock chambers are alternately connected in series, the load-lock chambers include at least a first load-lock chamber which is adjacent to the process unit on one side, and a second load-lock chamber which is adjacent to the process unit on the other side, the carriers include at least a first carrier which reciprocates between the first load-lock chamber and the process unit, and a second carrier which reciprocates between the second load-lock chamber and the process unit, and the transferring device synchronously transfers the first carrier and the second carrier in an identical direction.

The present invention also provides a vacuum processing method using the vacuum processing apparatus as defined above, comprising: an attachment step of attaching a substrate to the carrier positioned in the load-lock chamber; a transferring step of transferring the carrier, on which the substrate is mounted in the attachment step, to the process unit adjacent to the load-lock chamber; a vacuum processing step of performing vacuum processing on the substrate mounted on the carrier transferred into the process unit in the transferring step; a second transferring step of transferring the carrier, on which the substrate is mounted, to the load-lock chamber after the vacuum processing step; a second attachment step of attaching another substrate to another carrier positioned in another load-lock chamber which is adjacent to the process unit on the other side; and a third transferring step of transferring the other carrier, on which the other substrate is mounted in the second attachment step, to the process unit, wherein the second attachment step is performed during the vacuum processing step.

The present invention also provides a vacuum processing method using the vacuum processing apparatus as defined above, comprising: an attachment step of attaching a substrate to the carrier positioned in the load-lock chamber; a transferring step of transferring the carrier, on which the substrate is mounted in the attachment step, to a first process chamber adjacent to the load-lock chamber; a vacuum processing step of performing vacuum processing on the substrate mounted on the carrier transferred into the first process chamber in the transferring step; a second transferring step of transferring the carrier, on which the substrate having undergone the vacuum processing in the vacuum processing step is mounted, to a second process chamber adjacent to the load-lock chamber; a second vacuum processing step of performing vacuum processing on the substrate mounted on the carrier transferred into the second process chamber in the second transferring step; a third transferring step of transferring the carrier, on which the substrate is mounted, to the first process chamber after the second vacuum processing step; a second attachment step of attaching another substrate to another carrier positioned in another load-lock chamber which is adjacent to the second process chamber on the other side; and a fourth transferring step of transferring the other carrier, on which the other substrate is mounted in the second attachment step, to the second process unit, wherein the second attachment step is performed during the second vacuum processing step.

According to the present invention, it is possible to provide a vacuum processing apparatus which can improve the operating ratio of a process chamber (process unit) despite a small number of carriers. Also, this vacuum processing apparatus can perform continuous production using a small number of carriers even when, for example, repair and maintenance of these carriers are considered.

Further features of the present invention will become apparent from the following description of exemplary embodiments with reference to the attached drawings.

### BRIEF DESCRIPTION OF THE DRAWINGS

FIG. 1 is an external perspective view of a vacuum processing apparatus in the first embodiment according to the present invention;

FIG. 2 is a side view of the vacuum processing apparatus in the first embodiment;

FIG. 3 is a top view of the vacuum processing apparatus in the first embodiment;

FIG. 4 is a schematic view of the vacuum processing apparatus in the first embodiment;

FIGS. 5A and 5B are views for explaining the processing steps in the vacuum processing apparatus of the first embodiment;

FIGS. 6A and 6B are views for explaining the processing steps in the vacuum processing apparatus of the first embodiment;

FIG. 7 is a timing chart of processing in each chamber of the vacuum processing apparatus in the first embodiment;

FIG. 8 is a timing chart of processing in each chamber of the vacuum processing apparatus in the first embodiment;

FIGS. 9A and 9B are views for explaining the processing steps in a vacuum processing apparatus of the second embodiment;

FIGS. 10A to 10D are views for explaining the processing steps in a vacuum processing apparatus of the third embodiment;

FIGS. 11A to 11C are views for explaining the processing steps in a vacuum processing apparatus of the fourth embodiment; and

FIGS. 12A to 12D are views for explaining the processing steps in a vacuum processing apparatus of the fifth embodiment.

### DESCRIPTION OF THE EMBODIMENTS

Embodiments of the present invention will be described below with reference to the accompanying drawings. Note that members, arrangements, and other features to be described hereinafter merely give examples in which the present invention is embodied, and do not limit the present invention, so various modifications and changes can be made without departing from the scope of the present invention, as a matter of course.

Although a CVD deposition apparatus (a vacuum processing apparatus 1) which deposits DLC (Diamond-Like Carbon) will be taken as an example of a vacuum processing apparatus in the specification of the present invention, the present invention is not limited to this. The present invention is also suitably applicable to, for example, a sputtering apparatus, other PVD apparatuses, and other CVD apparatuses. The present invention is moreover suitably applicable to processing apparatuses other than a deposition apparatus, such as a dry etching apparatus, an ashing apparatus, and a heat treatment apparatus. Also, the vacuum processing apparatus according to the present invention can be suitably adopted as a fuel cell manufacturing apparatus, a panel manufacturing apparatus, a semiconductor manufacturing apparatus, and a storage manufacturing apparatus.

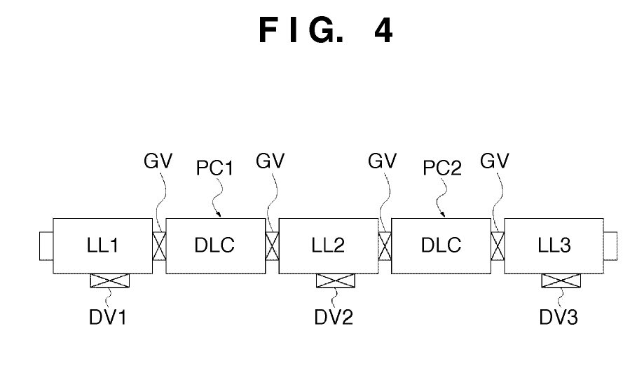

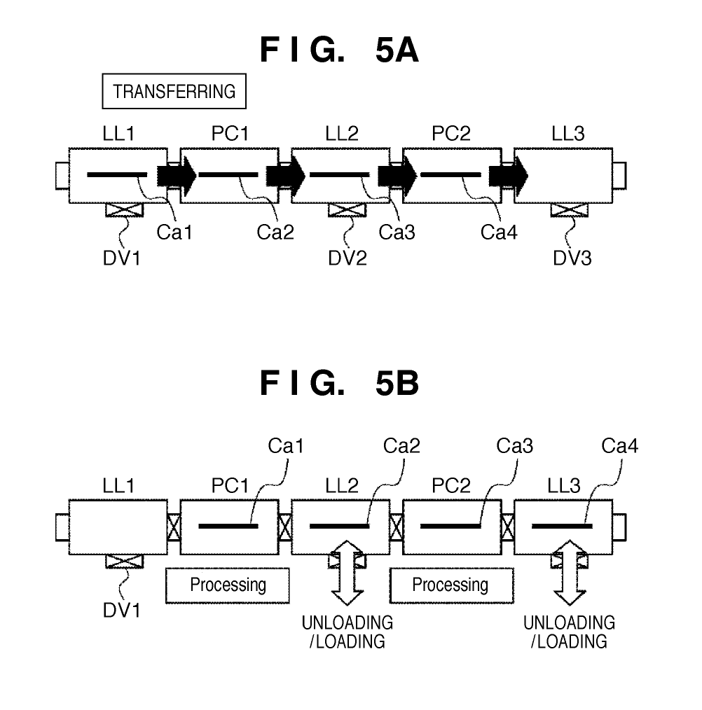

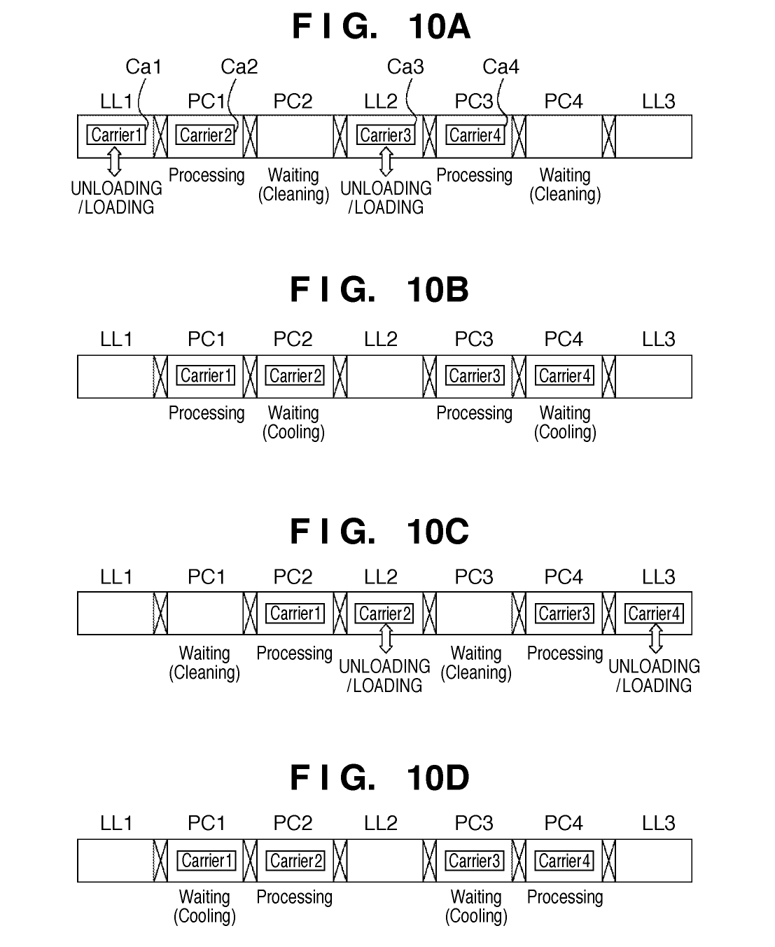

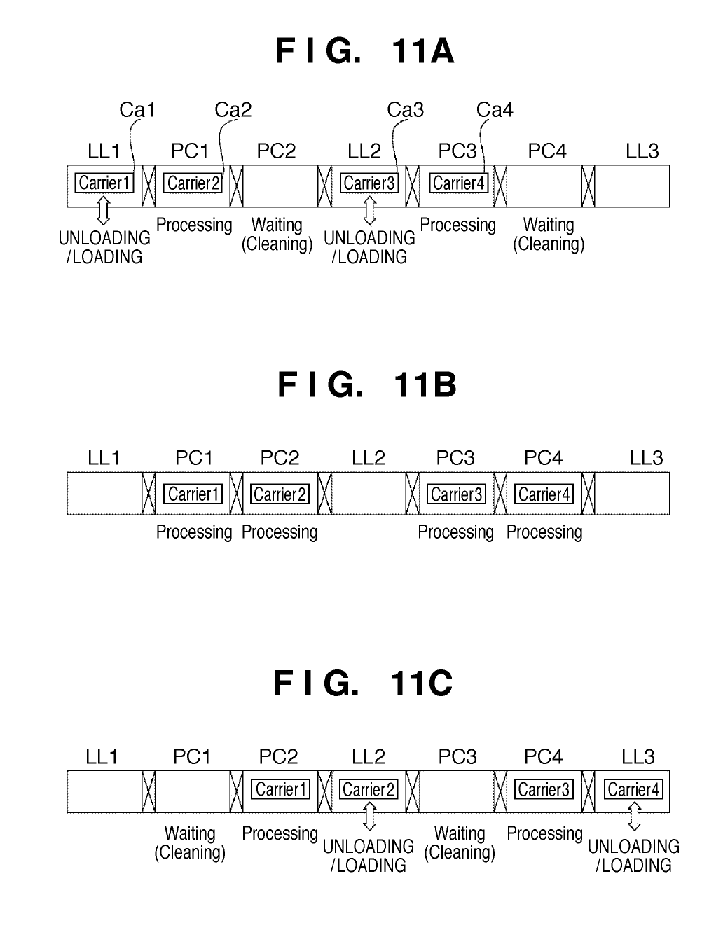

In this specification, a “process unit” includes not only process chambers PC shown in FIGS. 4 and 5 but also a series of regions (for example, continuous chambers such as process chambers PC1 and PC2 shown in FIGS. 10 and 11) in which the vacuum processing apparatus performs vacuum processing. In contrast, a “process chamber” means an individual process chamber such as the process chamber PC1.

In this specification, a load-lock chamber which is adjacent to an arbitrary process chamber on one side is defined as a first load-lock chamber, and that which is adjacent to this process chamber on the other side is defined as a second load-lock chamber. A first carrier and a second carrier mean two arbitrary carriers, which are juxtaposed to each other, among carriers Ca1 to Ca6.

### First Embodiment

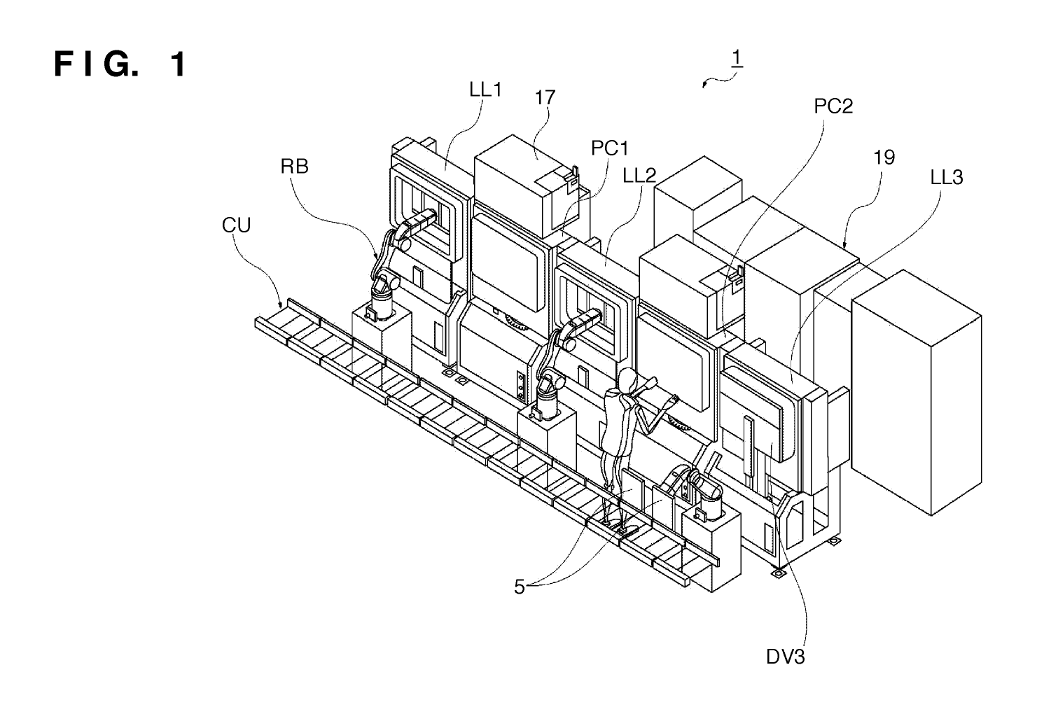

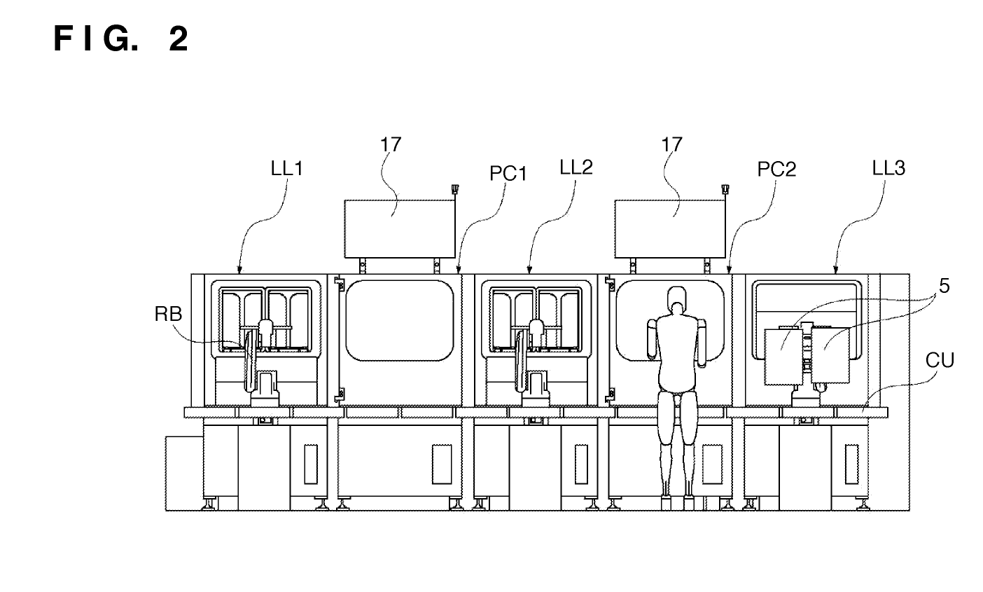

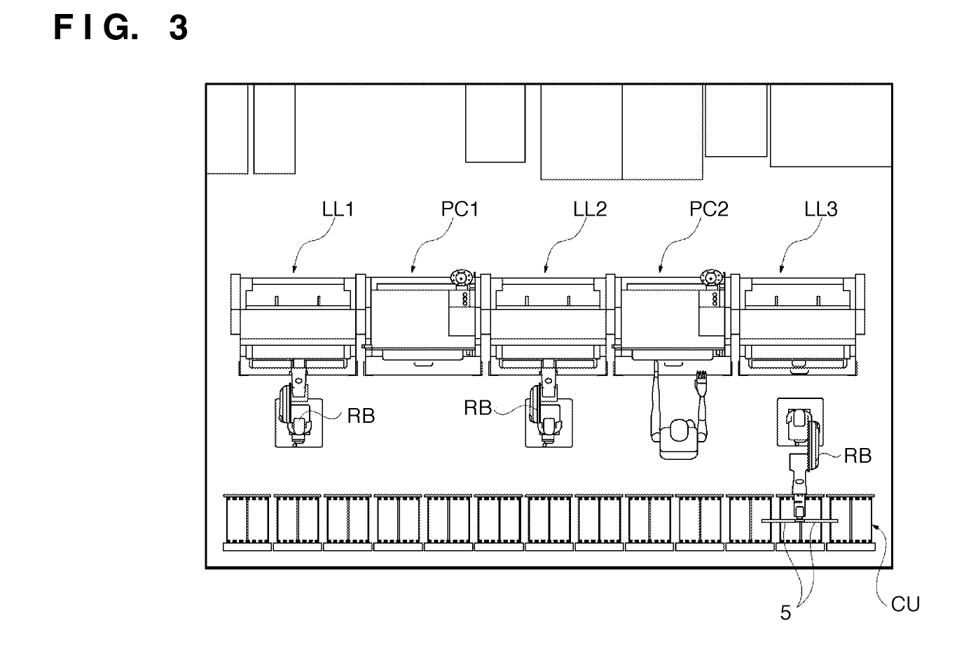

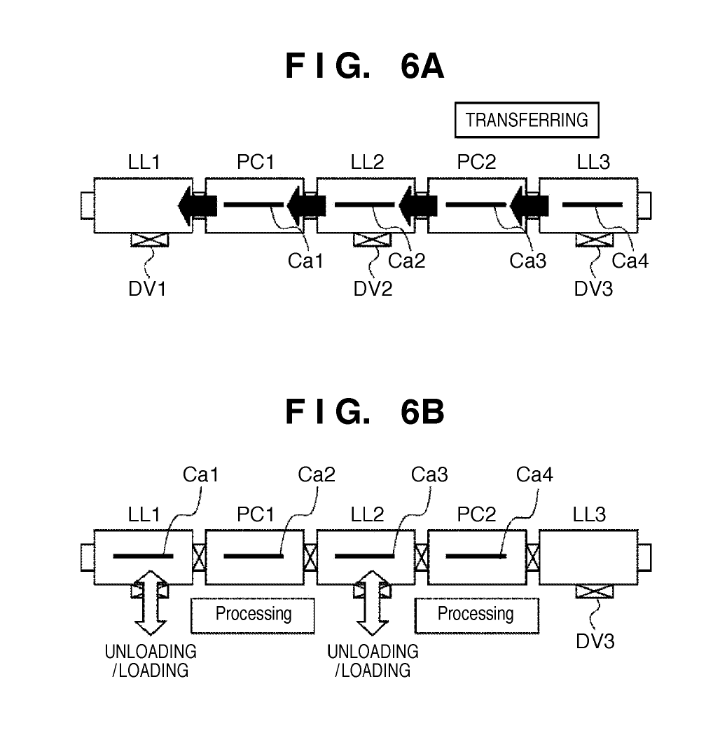

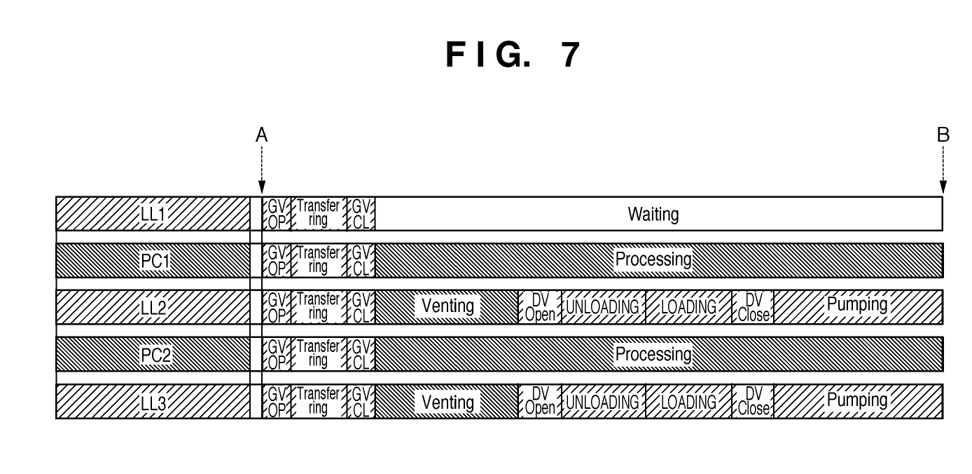

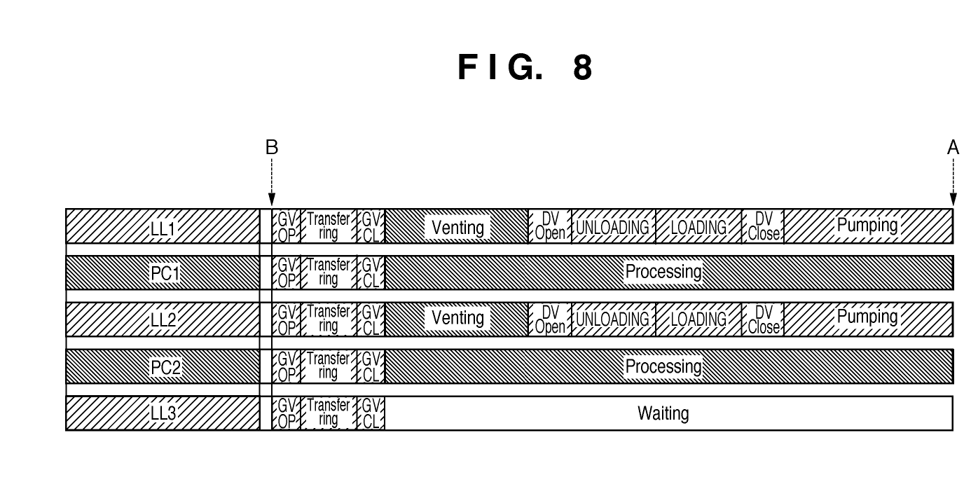

FIGS. 1 to 8 are views showing a vacuum processing apparatus according to the first embodiment of the present invention, in which FIG. 1 is an external perspective view of the vacuum processing apparatus; FIG. 2 is a side view of the vacuum processing apparatus; FIG. 3 is a top view of the vacuum processing apparatus; FIG. 4 is a schematic view of the configuration of the vacuum processing apparatus; FIGS. 5A, 5B, 6A, and 6B are explanatory views showing the processing steps in the vacuum processing apparatus; and FIGS. 7 and 8 are timing charts of processing in each chamber of the vacuum processing apparatus. Note that some elements are not shown in these drawings to avoid their complications.

The schematic configuration of a vacuum processing apparatus 1 will be described with reference to FIGS. 1 to 4. FIGS. 1 to 3 show the outer appearances of the vacuum processing apparatus, and FIG. 4 is a schematic view of the configuration of the vacuum processing apparatus. The vacuum processing apparatus 1 is a CVD apparatus, which is formed by connecting five vacuum chambers in series. That is, in the vacuum processing apparatus 1, a load-lock chamber LL1, a process chamber PC1, a load-lock chamber LL2, a process chamber PC2, and a load-lock chamber LL3 are connected in series via gate valves GV in this order. The vacuum processing apparatus 1 performs vacuum processing while holding a substrate on a carrier. Also, the vacuum processing apparatus 1 is provided with a transferring device which transfers the carrier between respective vacuum chambers.

The process chamber PC (process chambers PC1 and PC2) is a CVD-process chamber for depositing DLC (Diamond-Like Carbon), and includes, for example, a gas introduction system 17, a power supply system 19, and an exhaust system although a detailed description thereof will not be given. Examples of a gas introduced from the gas introduction system 17 are CₓH_{y} (hydrocarbon-based gas), H₂, N₂, and Ar. The process chamber PC includes a CVD processing apparatus which deposits a DLC film, an ashing processing apparatus, and a heater which heats a substrate 5 to a predetermined temperature.

The load-lock chamber LL (load-lock chambers LL1, LL2, and LL3) functions both as a load chamber for loading a substrate and an unload chamber for unloading it, and includes a gas introduction system and exhaust system (neither is shown). The load-lock chambers LL are connected to the process chamber PC, for performing the process, on its two sides via the gate valves GV so as to load/unload the substrate 5 (target material) to/from the process chamber PC from its two sides. The load-lock chamber LL has a mechanism which repeatedly evacuates/vents the load-lock chambers LL, and loads/unloads the substrate 5 to/from the apparatus. That is, an operation of attaching (mounting) or detaching the substrate 5 to or from the carrier can be performed by opening a door valve DV (door valves DV1, DV2, and DV3).

Robots RB and a conveyor CU are disposed around the vacuum processing apparatus 1, so the substrate 5 transferred by the conveyor CU from the upstream step can be attached to the carrier by the robot RB. The processed substrate 5 is removed from the carrier, placed on the conveyor CU, and transferred to the downstream step by the robot RB. In this embodiment, although the robot RB is used to replace the substrate, another replacement method may be adopted. Note that the processing steps will be described in detail with reference to FIGS. 5A, 5B, 6A, and 6B.

The transferring device which transfers the carrier will be described herein. First, the carrier is a member which holds the substrate 5, as described above, and has racks that are attached on its lower portion in series and mesh with pinions of the transferring device. The transferring device is provided on the vacuum chamber side and transfers the carrier to predetermined positions in the process chamber PC and load-lock chamber LL. The transferring device has pinions which are arranged with predetermined spacings between them and serve as rotationally controllable small gears. Because the pinions of the transferring device mesh with the racks of the carrier, the carrier can be transferred to an arbitrary position by controlling rotation of the pinions.

A pinion adjacent to a given pinion meshes with the rack of the carrier before the carrier is transferred to the position where it does not mesh with the given pinion. The transferring device in this embodiment is equipped with four carriers, and each carrier is transferred to reciprocate between the load-lock chambers LL and process chambers PC which are adjacent to each other. Because all pinions rotate synchronously, the four carriers also move synchronously. All carriers synchronously move in the same direction.

Although the substrate is a plate-like or sheet-like member in this embodiment, it can be changed as needed in accordance with the purpose of vacuum processing. Also, the above-mentioned transferring device merely gives one configuration example, and a mechanism which uses a magnetic screw or a linear motor, for example, may be adopted in place of the mechanism which uses racks and pinions.

FIGS. 5A, 5B, 6A, and 6B are explanatory views showing the processing steps in the vacuum processing apparatus, and show the sequence of the processing steps. That is, predetermined vacuum processing and transferring operation are performed in the order of the steps shown in FIGS. 5A, 5B, 6A, and 6B. FIG. 5A shows a step (transferring step) of transferring carriers Ca1 to Ca4 after completion of vacuum processing in the process chambers PC1 and PC2. At this time, the carriers Ca1 and Ca3 hold (mount) the substrates to be processed, while the carriers Ca2 and Ca4 hold the processed substrates. That is, at the same time as the carriers Ca2 and Ca4 move to the load-lock chambers LL2 and LL3, respectively, upon completion of vacuum processing in the process chambers PC1 and PC2, respectively, the carriers Ca1 and Ca3 move to the process chambers PC1 and PC2, respectively, to start vacuum processing.

FIG. 5B shows a step (vacuum processing step) of performing vacuum, processing in the process chambers PC1 and PC2 after completion of the transferring step shown in FIG. 5A. At this time, the substrates held on the carriers Ca1 and Ca3 undergo vacuum processing in the process chambers PC1 and PC2, respectively. At the same time, an operation of detaching the processed substrates from the carriers Ca2 and Ca4, and attaching substrates to be processed to them (attachment step) is performed. More specifically, four steps (operation steps): ventilation (exposure to the atmosphere), substrate unloading/loading, and vacuum exhaust are performed in the load-lock chambers LL2 and LL3 during vacuum processing in the process chambers PC1 and PC2.

FIG. 6A shows a step (second transferring step) of transferring the carriers Ca1 to Ca4 after completion of the step shown in FIG. 5B. At this time, the carriers Ca2 and Ca4 hold (mount) the substrates to be processed, while the carriers Ca1 and Ca3 hold the processed substrates. The direction to transfer the carriers in FIG. 6A is opposite to that in FIG. 5A.

FIG. 6B shows a step (second vacuum processing step) of performing vacuum processing in the process chambers PC1 and PC2 after completion of the transferring step shown in FIG. 6A. That is, at the same time as the carriers Ca1 and Ca3 move to the load-lock chambers LL1 and LL2, respectively, upon completion of vacuum processing in the process chambers PC1 and PC2, respectively, the carriers Ca2 and Ca4 move to the process chambers PC1 and PC2, respectively, to start vacuum processing. At this time, the substrates held on the carriers Ca2 and Ca4 undergo vacuum processing in the process chambers PC1 and PC2, respectively. Also, an operation of detaching the processed substrates from the carriers Ca1 and Ca3, and attaching substrates to be processed to them (second attachment step) is performed. Note that operation steps of ventilation (exposure to the atmosphere), substrate unloading/loading, and vacuum exhaust are performed in the load-lock chambers LL1 and LL2, as in the above-mentioned operation steps shown in FIG. 5B.

After the step shown in FIG. 6B, the step (a transferring step or a third transferring step) shown in FIG. 5A is performed. In other words, the vacuum processing apparatus 1 continuously processes a large number of substrates by repeating the above-mentioned steps shown in FIGS. 5A, 5B, 6A, and 6B.

FIGS. 7 and 8 are timing charts of processing in each chamber of the vacuum processing apparatus. FIG. 7 is a timing chart of processing in each chamber in the step shown in FIG. 5B. More specifically, four steps (operation steps): ventilation (exposure to the atmosphere), substrate unloading/loading, and vacuum exhaust are performed in the load-lock chambers LL2 and LL3 during vacuum processing in the process chambers PC1 and PC2. FIG. 8 is a timing chart of processing in each chamber in the step shown in FIG. 6B. More specifically, four steps (operation steps): ventilation (exposure to the atmosphere), substrate unloading/loading, and vacuum exhaust are performed in the load-lock chambers LL1 and LL2 during vacuum processing in the process chambers PC1 and PC2.

As can be seen by referring to FIGS. 7 and 8, as a whole, the vacuum processing apparatus 1 according to this embodiment performs efficient equipment application with a high operating ratio. This is obvious from the fact that the operation times in the load-lock chambers LL2 and LL3 or LL1 and LL2, and the times required for vacuum processing in the process chambers PC1 and PC2, are nearly equal to each other, so no standby times occur in these chambers. Note that reference symbols A and B in FIGS. 7 and 8 denote the same timings. That is, the processing shown in FIG. 7 and that shown in FIG. 8 are repeatedly performed.

### Second Embodiment

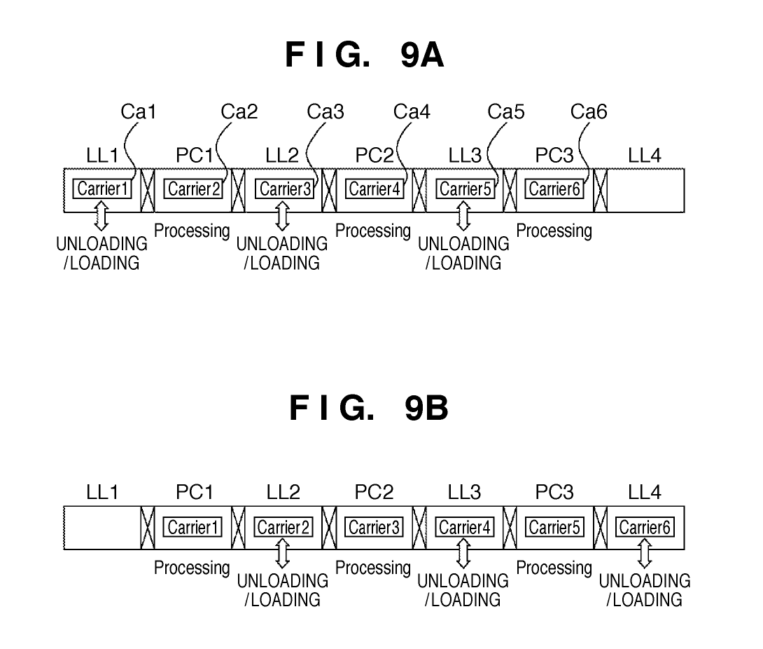

FIGS. 9A and 9B are explanatory views showing the processing steps in a vacuum processing apparatus according to the second embodiment of the present invention. A vacuum processing apparatus 2 according to this embodiment repeatedly performs vacuum processing shown in FIGS. 9A and 9B. A carrier transferring step performed in the interval between the steps shown in FIGS. 9A and 9B is not shown. FIG. 9B shows a step (second vacuum processing step) of performing vacuum processing in process chambers PC1, PC2, and PC3 after a transferring step is performed upon completion of the vacuum processing (vacuum processing step) shown in FIG. 9A and substrate unloading/loading (attachment step). At this time, the substrates held on carriers Ca1, Ca3, and Ca5 undergo vacuum processing in the process chambers PC1, PC2, and PC3, respectively. At the same time, an operation of detaching the processed substrates from carriers Ca2, Ca4, and Ca6, and attaching substrates to be processed to them (second attachment step) is performed. More specifically, four steps (operation steps): ventilation (exposure to the atmosphere), substrate unloading/loading, and vacuum exhaust are performed in load-lock chambers LL2, LL3, and LL4 during vacuum processing in the process chambers PC1, PC2, and PC3.

### Third Embodiment

FIGS. 10A to 10D are explanatory views showing the processing steps in a vacuum processing apparatus according to the third embodiment of the present invention. A vacuum processing apparatus 3 according to this embodiment repeatedly performs vacuum processing shown in FIGS. 10A, 10B, 100, and 10D. Carrier transferring steps which are performed in the interval (transferring step) between the steps shown in FIGS. 10A and 10B, that (second transferring step) between the steps shown in FIGS. 10B and 10C, that (third transferring step) between the steps shown in FIGS. 10C and 10D, and that (fourth transferring step) between the steps shown in FIGS. 10D and 10A are not shown.

FIG. 10B shows a step of performing vacuum processing in process chambers PC1, PC2, PC3, and PC4 after a transferring step (transferring step) is performed upon completion of the vacuum processing (vacuum processing step) shown in FIG. 10A and substrate unloading/loading (attachment step). At this time, the substrates held on carriers Ca1 and Ca3 undergo vacuum processing in the process chambers PC1 and PC3 (first process chambers), respectively (vacuum processing step). At the same time, the substrates which are held on carriers Ca2 and Ca4 and processed in the process chambers PC1 and PC3, respectively, in FIG. 10A stand by in the process chambers PC2 and PC4 (second process chambers), respectively, or undergo vacuum processing such as cooling as needed. FIG. 100 shows a step (second vacuum processing step) of performing vacuum processing in the process chambers PC2 and PC4 after a transferring step (second transferring step) is performed upon completion of the vacuum processing (vacuum processing step) shown in FIG. 10B.

At this time, the substrates held on the carriers Ca1 and Ca3 undergo vacuum processing in the process chambers PC2 and PC4, respectively. At the same time, an operation of detaching the processed substrates from the carriers Ca2 and Ca4, and attaching substrates to be processed to them (second attachment step) is performed. More specifically, four steps (operation steps): ventilation (exposure to the atmosphere), substrate unloading/loading, and vacuum exhaust are performed in load-lock chambers LL2 and LL3 during vacuum processing in the process chambers PC2 and PC4.

FIG. 10D shows a step of performing vacuum processing in the process chambers PC1, PC2, PC3, and PC4 after a transferring step (third transferring step) is performed upon completion of the vacuum processing shown in FIG. 10C and substrate unloading/loading. At this time, the substrates held on the carriers Ca2 and Ca4 undergo vacuum processing in the process chambers PC2 and PC4, respectively. At the same time, the substrates which are held on carriers Ca1 and Ca3 and processed in the process chambers PC2 and PC4, respectively, in FIG. 10C stand by in the process chambers PC1 and PC3, respectively, or undergo vacuum processing such as cooling as needed.

In other words, the substrate held on the carrier Ca1 is transferred in the order of PC1-PC2-(PC1), and that held on the carrier Ca2 is transferred in the order of PC1-PC2-(PC2). Similarly, the substrate held on the carrier Ca3 is transferred in the order of PC3-PC4-(PC3), and that held on the carrier Ca4 is transferred in the order of PC4-PC3-(PC4). That is, after the substrate undergoes vacuum processing in each process chamber PC, it is unloaded from the load-lock chamber LL.

### Fourth Embodiment

FIGS. 11A to 11C are explanatory views showing the processing steps in a vacuum processing apparatus according to the fourth embodiment of the present invention. A vacuum processing apparatus 4 according to this embodiment repeatedly performs vacuum processing shown in FIGS. 11A, 11B, and 11C.

Carrier transferring steps which are performed in the interval between the steps shown in FIGS. 11A and 11B, that between the steps shown in FIGS. 11B and 11C, and that between the steps shown in FIGS. 11C and 11A are not shown. FIG. 11B shows a step of performing vacuum processing in process chambers PC1, PC2, PC3, and PC4 after a transferring step is performed upon completion of the vacuum processing (vacuum processing step) shown in FIG. 11A and substrate unloading/loading.

At this time, substrates which are newly loaded into the apparatus in FIG. 11A and held on carriers Ca1 and Ca3 undergo vacuum processing in the process chambers PC1 and PC3, respectively. At the same time, the substrates which are held on carriers Ca2 and Ca4 and processed in the process chambers PC1 and PC3, respectively, in FIG. 11A undergo vacuum processing in the process chambers PC2 and PC4, respectively. FIG. 11C shows a step of performing vacuum processing in the process chambers PC2 and PC4 after a transferring step is performed upon completion of the vacuum processing shown in FIG. 11B.

At this time, the substrates held on the carriers Ca1 and Ca3 undergo vacuum processing in the process chambers PC2 and PC4, respectively. At the same time, an operation of detaching the processed substrates from the carriers Ca2 and Ca4, and attaching substrates to be processed to them is performed. More specifically, four steps (operation steps): ventilation (exposure to the atmosphere), substrate unloading/loading, and vacuum exhaust are performed in load-lock chambers LL2 and LL3 during vacuum processing in the process chambers PC2 and PC4. In other words, after the substrates held on the carriers Ca1 and Ca2 and those held on the carriers Ca3 and Ca4 undergo processing, the two former substrates are unloaded in the order of PC1-PC2, and the two latter substrates are unloaded in the order of PC2-PC1.

### Fifth Embodiment

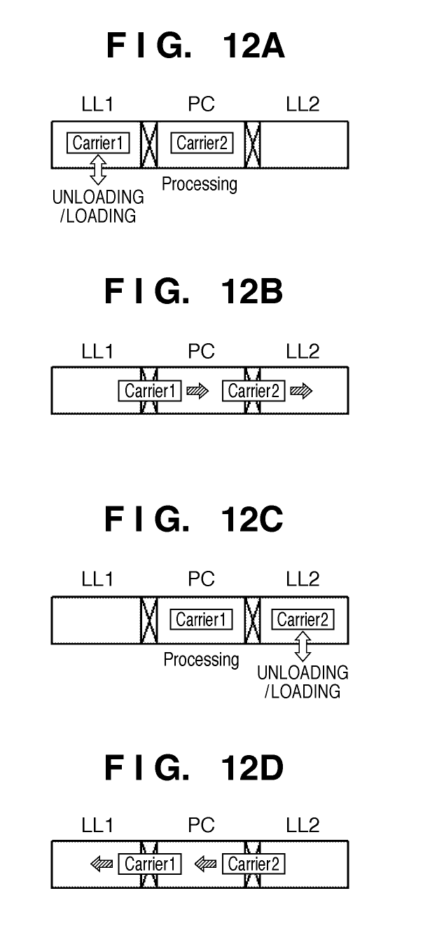

FIGS. 12A to 12D are explanatory views showing the processing steps in a vacuum processing apparatus according to the fifth embodiment of the present invention. A vacuum processing apparatus 5 according to this embodiment has a three-chamber configuration in which load-lock chambers LL are disposed on the two sides of one process chamber PC. In the vacuum processing apparatus 5, two carriers Ca are alternately positioned in a process chamber PC.

FIG. 12A shows a step performed after a carrier transferring step (transferring step), that is, a step (vacuum processing step) of performing vacuum processing in the process chamber PC while a substrate is unloaded/loaded in a load-lock chamber LL1 (attachment step). FIG. 12C shows a step (second vacuum processing step) of performing vacuum processing in the process chamber PC while a substrate is unloaded/loaded in a load-lock chamber LL2 (second attachment step). More specifically, four steps (operation steps): ventilation (exposure to the atmosphere), substrate unloading/loading, and vacuum exhaust are performed in the load-lock chambers LL1 and LL2 during vacuum processing in the process chamber PC. FIG. 12B shows a carrier transferring step (second transferring step) performed before the step shown in FIG. 12C after the step shown in FIG. 12A. Also, FIG. 12D shows a carrier transferring step (a third transferring step or a transferring step) performed before the step shown in FIG. 12A after the step shown in FIG. 12C.

Although a configuration example in which two or four process chambers PC (four or six load-lock chambers LL) are used has been described in the first to fifth embodiments, the number and configuration of chambers can be changed as needed, as a matter of course.

If the process chambers PC and the load-lock chambers LL can be arranged in a predetermined order, the number of process chambers PC can be arbitrarily set. The vacuum processing apparatus may include, for example, 12 process chambers PC and 13 load-lock chambers LL. In this manner, if the process chambers PC and the load-lock chambers LL are alternately connected in series, the load-lock chambers LL are more than the process chambers PC by one. Also, the leading and trailing ends of the chambers PC or LL which are connected in series may be connected.

That is, if process units each including two process chambers PC are provided, N+1 load-lock chambers and N+1 carriers are used, so the transferring device can synchronously transfer a set of two carriers. Note that if the number of process chambers PC which constitute each process unit is not specified, N+1 load-lock chambers and N×2 or fewer carriers are used for N process units, so the transferring device synchronously transfers a set of two or more carriers.

As another example, an arbitrary number of process chambers PC can be used in a configuration in which load-lock chambers LL are provided on the two sides of a set of a plurality of process chambers PC, as in cases of FIGS. 10A to 10D and 11A to 11C. Even in this case, units each including a plurality of process chambers PC and load-lock chambers LL on the two sides of a set of them may be arbitrarily connected in series.

However, vacuum processing apparatuses having the configurations as shown in FIGS. 10A to 10D and 11A to 11C can be regarded as including process units and load-lock chambers LL which are alternately connected in series, assuming a plurality of continuous process chambers PC (adjacent process chambers such as the process chambers PC1 and PC2) as one process unit. The use of the vacuum processing apparatus 1, 2, 3, 4, or 5 according to the present invention mentioned above makes it possible to improve the operating ratio of the process chamber despite a small number of carriers. Also, the vacuum processing apparatus according to the present invention can perform continuous production using a small number of carriers even when, for example, repair and maintenance of these carriers are considered. This makes it possible to further reduce the cost required for production, such as the running cost and the equipment cost.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application Nos. 2010-046043, filed Mar. 3, 2010 and 2010-278803, filed Dec. 15, 2010, which are hereby incorporated by reference herein in their entireties.

What is claimed is:

1. A vacuum processing apparatus comprising:
not less than one process unit;
load-lock chambers which are more than the process unit by one;
carriers which are more than the process unit by not less than one; and
a transferring device which transfers the carriers between the process unit and the load-lock chambers that are adjacent to each other,
wherein
the process unit and the load-lock chambers are alternately connected in series,
the load-lock chambers include at least a first load-lock chamber which is adjacent to the process unit on one side, and a second load-lock chamber which is adjacent to the process unit on the other side,
the carriers include at least a first carrier which reciprocates between the first load-lock chamber and the process unit, and a second carrier which reciprocates between the second load-lock chamber and the process unit, and
the transferring device synchronously transfers the first carrier and the second carrier in an identical direction.

2. The apparatus according to claim 1, further comprising:
N process units;
N+1 load-lock chambers; and
not less than N×2 carriers,
wherein the transferring device synchronously transfers a set of not less than two carriers among the carriers.

3. The apparatus according to claim 1, wherein if not less than two process units are present, the transferring device synchronously transfers all of the carriers in an identical direction.

4. A vacuum processing method using the vacuum processing apparatus according to claim 1, comprising:
an attachment step of attaching a substrate to the carrier positioned in the load-lock chamber;
a transferring step of transferring the carrier, on which the substrate is mounted in the attachment step, to the process unit adjacent to the load-lock chamber;
a vacuum processing step of performing vacuum processing on the substrate mounted on the carrier transferred into the process unit in the transferring step;
a second transferring step of transferring the carrier, on which the substrate is mounted, to the load-lock chamber after the vacuum processing step;
a second attachment step of attaching another substrate to another carrier positioned in another load-lock chamber which is adjacent to the process unit on the other side; and
a third transferring step of transferring the other carrier, on which the other substrate is mounted in the second attachment step, to the process unit,
wherein the second attachment step is performed during the vacuum processing step.

5. The method using the vacuum processing apparatus according to claim 1, wherein the process unit includes a plurality of continuous process chambers.

6. A vacuum processing method using the vacuum processing apparatus according to claim 5, comprising:
an attachment step of attaching a substrate to the carrier positioned in the load-lock chamber;
a transferring step of transferring the carrier, on which the substrate is mounted in the attachment step, to a first process chamber adjacent to the load-lock chamber;
a vacuum processing step of performing vacuum processing on the substrate mounted on the carrier transferred into the first process chamber in the transferring step;
a second transferring step of transferring the carrier, on which the substrate having undergone the vacuum processing in the vacuum processing step is mounted, to a second process chamber adjacent to the load-lock chamber;
a second vacuum processing step of performing vacuum processing on the substrate mounted on the carrier transferred into the second process chamber in the second transferring step;
a third transferring step of transferring the carrier, on which the substrate is mounted, to the first process chamber after the second vacuum processing step;
a second attachment step of attaching another substrate to another carrier positioned in another load-lock chamber which is adjacent to the second process chamber on the other side; and
a fourth transferring step of transferring the other carrier, on which the other substrate is mounted in the second attachment step, to the second process unit,
wherein the second attachment step is performed during the second vacuum processing step.
